(19) United States
(12) Patent Application Publication
(10) Pub. No.: US 2014/0232293 A1
(43) Pub. Date: Aug. 21, 2014

(54) LIGHT-EMITTING DEVICE PACKAGE

(71) Applicant: SAMSUNG ELECTRONICS CO., LTD., Suwon-si (KR)

(72) Inventors: Dong-hyuck KAM, Hwaseong-si (KR); Gam-han YONG, Suwon-si (KR); Sang-hyun LEE, Suwon-si (KR); Seong-deok HWANG, Seoul (KR)

(73) Assignee: SAMSUNG ELECTRONICS CO., LTD., Suwon-si (KR)

(21) Appl. No.: 14/082,991

(22) Filed: Nov. 18, 2013

(30) Foreign Application Priority Data
Feb. 18, 2013 (KR) 10-2013-0016971

(51) Int. Cl. H01L 33/62; H05B 33/08; H01L 33/08

(52) U.S. Cl. CPC H01L 33/62; H01L 33/08; H05B 33/0842
USPC 315/294; 257/99; 257/88

(57) ABSTRACT

The present application provides a light-emitting device package. The light-emitting device package includes a package substrate includes at least one via hole. A light-emitting device is mounted on the package substrate so as to overlap with the via hole. A bonding layer is formed between the light-emitting device and the package substrate and includes a eutectic bonding material.

### CROSS-REFERENCE TO RELATED APPLICATIONS

This application claims the benefit of priority under 35 U.S.C. §119 to Korean Patent Application No. 10-2013-0016971, filed on Feb. 18, 2013, in the Korean Intellectual Property Office, the disclosure of which is incorporated herein in its entirety by reference.

### TECHNICAL FIELD

The inventive concept relates to a light-emitting device package, and more particularly, to a light-emitting device package which employs a wafer level package.

### BACKGROUND

A wafer level packaging method is being developed. In the method, a plurality of light-emitting devices are mounted on one package substrate, and the package substrate is separated to form a plurality of light-emitting device packages. There is a further need for a light-emitting device package having good reliability and a method of manufacturing thereof.

### SUMMARY

The inventive concept provides a light-emitting device package including a light-emitting device having good reliability.

According to an aspect of the inventive concept, there is provided a light-emitting device package. The package includes a package substrate having at least one via hole. A light-emitting device is mounted on the package substrate so as to overlap with the at least one via hole A bonding layer is formed between the light-emitting device and the package substrate and includes a eutectic bonding material.

The bonding layer may be formed to overlap with the at least one via hole, and covers an upper part of the at least one via hole.

The bonding layer may include a protruding part which protrudes downwards in an area in which the bonding layer overlaps with the at least one via hole.

The protruding part may extend to a sidewall of the at least one via hole.

A cavity having a predetermined depth from an upper surface of the package substrate may be formed on the package substrate, and the light-emitting device may be mounted inside the cavity.

An area of the cavity may be greater than an area of the light-emitting device.

The cavity may communicate with the at least one via hole.

The light-emitting package may further include at least one via hole through the package substrate; and a through substrate via which is formed inside the at least one via hole and which includes a conductive material.

A part of an inside of the at least one via hole may be vacant.

A part of the inside of the at least one via hole may be filled with a filler which is an insulating material.

The entire inside of the at least one via hole may be vacant.

According to another aspect of the inventive concept, there is provided a light-emitting device package, including a package substrate which includes a plurality of light-emitting device mounting areas. A plurality of light-emitting devices are respectively mounted in the plurality of light-emitting device mounting areas. A plurality of via holes passes through the package substrate, and each of the plurality of via holes is formed in each of the plurality of light-emitting device mounting areas of the package substrate.

The light-emitting package of claim may further include bonding layers formed below the light-emitting devices and include a eutectic bonding material. Wiring lines are formed in a part of the plurality of light-emitting device mounting areas on the package substrate. The bonding layers and the wiring lines contact each other and are electrically connected to each other.

The bonding layers may include protruding parts which protrude downwards toward the plurality of via holes in an area which overlaps with the plurality of via holes.

The protruding parts may contact a part of an inner wall of the plurality of via holes.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

Exemplary embodiments of the inventive concept will be more clearly understood from the following detailed description taken in conjunction with the accompanying drawings in which:

FIG. 1 is a perspective view illustrating a package substrate for a light-emitting device according to an exemplary embodiment of the inventive concept;

FIG. 2 is a perspective view illustrating a package substrate for a light-emitting device according to another exemplary embodiment of the inventive concept;

FIG. 3 is a cross-sectional view illustrating a light-emitting device package according to an exemplary embodiment of the inventive concept;

FIG. 4 is a cross-sectional view illustrating a light-emitting device package according to another exemplary embodiment of the inventive concept;

FIG. 5 is a cross-sectional view illustrating a light-emitting device package according to another exemplary embodiment of the inventive concept;

FIG. 6 is a cross-sectional view illustrating a light-emitting device package according to another exemplary embodiment of the inventive concept;

FIGS. 7A through 7F are cross-sectional views illustrating a method of manufacturing a light-emitting device package according to an exemplary embodiment of the inventive concept;

FIG. 8 is a cross-sectional view illustrating a method of manufacturing a light-emitting device package according to another exemplary embodiment of the inventive concept;

FIG. 9 is a cross-sectional view illustrating a method of manufacturing a light-emitting device package according to an exemplary embodiment of the inventive concept; and

FIG. 10 is a configuration map of a light-emitting device system which employs the light-emitting device package according to exemplary embodiments of the inventive concept.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

Hereinafter, exemplary embodiments of the inventive concept will be described in detail with reference to the accompanying drawings, in which exemplary embodiments of the application are shown.

This application may, however, be embodied in many different forms and should not be construed as limited to the exemplary embodiments set forth herein. Rather, these embodiments are provided so that this disclosure will be thorough and complete, and will fully convey the scope of the inventive concept to those of ordinary skilled in the art. In the drawings, the lengths and sizes of layers and areas may be exaggerated for clarity.

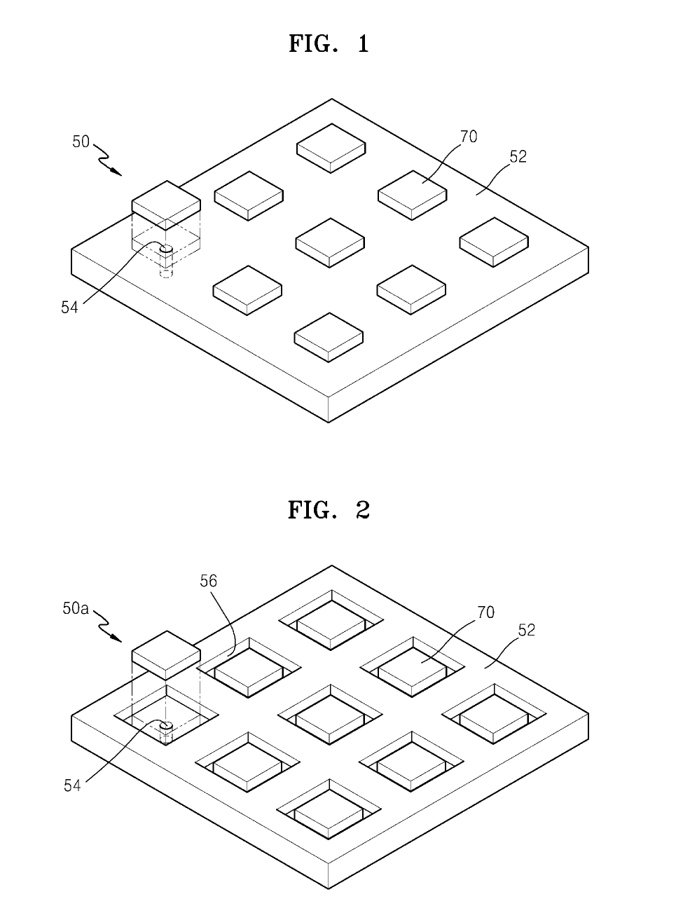

FIG. 1 is a perspective view illustrating a package substrate 50 for a light-emitting device according to exemplary embodiments of the inventive concept. FIG. 1 shows that a plurality of light-emitting devices 70 are mounted on the package substrate 50.

Referring to FIG. 1, the package substrate 50 may include a substrate 52 in which a plurality of first via holes 54 are formed. Additionally, although not illustrated, the package substrate 52 may further include wiring lines (not illustrated) which are formed on the substrate 52 or through substrate vias (not illustrated) for implementing a wiring connection.

A plurality of the first via holes 54 may be formed to overlap with areas in which each of the light-emitting devices 70 are mounted. The first via holes 54 may function as vacuum suction paths, that is, suction holes for temporarily fixing the light-emitting devices 70 on the substrate 52.

The package substrate 50 may be a substrate for a wafer-level package in which a plurality of the light-emitting devices 70 are simultaneously bonded to the package substrate 50, package processes such as wiring, forming of a fluorescent layer, forming of a lens are performed, and then, a plurality of the light-emitting devices 70 are separated into respective light-emitting device packages.

With regard to the package substrate 50 according to the inventive concept, the light-emitting devices 70 may be located on the package substrate 50 by suctioning air from below the first via holes 54 and thus, temporarily fixing the light-emitting devices 70, and then, performing a high-temperature bonding process. Accordingly, alignment precision of the light-emitting devices 70 may be improved. Additionally, by simultaneously heating temporarily fixed light-emitting devices 70, a period of time during which the light-emitting devices 70 are exposed to a high temperature for eutectic bonding may be minimized, and thus, damage to or performance deterioration of the light-emitting devices 70 may be prevented.

FIG. 2 is a perspective view illustrating a package substrate 50a for the light-emitting device according to an exemplary embodiment of the inventive concept. The package substrate 50a for the light-emitting device is similar to the package substrate 50 for the light-emitting device, except that cavities 56 are further formed on the package substrate 50a for the light-emitting device.

Referring to FIG. 2, the package substrate 50a may include the substrate 52 in which a plurality of the first via holes 54 and a plurality of the cavities 56 are formed. Additionally, although not illustrated, the package substrate 50a may further include wiring lines (not illustrated) which are formed on the substrate 52 or through substrate vias (not illustrated) for wiring connection.

A plurality of the cavities 56 are formed to have a predetermined depth from an upper surface of the substrate 52. A size of the respective cavities 56 are formed to be larger than a size of the light-emitting devices 70. Thus, at least one light-emitting device 70 may be mounted in each of the cavities 56. For example, a plurality of the cavities 56 may be arranged in the form of a matrix on the substrate 52. Additionally, a layout of the cavities 56 may vary with a layout of a plurality of the light-emitting devices 70. FIG. 2 shows that a depth of the cavities 56 is less than a height of the light-emitting devices 70. However, a depth of the cavities 56 is not limited thereto.

A plurality of the first via holes 54 may be formed through the substrate 52, and each of the first via holes 54 may be formed to communicate with each of the cavities 56. Accordingly, the light-emitting devices 70 and the first via holes 54 may be formed to overlap with each other. FIG. 2 shows that one first via hole 54 overlaps with each of the cavities 56. However, a plurality of the first via holes 54 may be formed to overlap with each of the cavities 56.

With regard to the package substrate 50a according to the inventive concept, the light-emitting devices 70 may be located on the package substrate 50a by suctioning air from below the first via holes 54 and thus, temporarily fixing the light-emitting devices 70, and then, by performing a high-temperature bonding process. Accordingly, a period of time during which the light-emitting device is exposed to a high temperature for eutectic bonding may be minimized, and thus, damage to or performance deterioration of the light-emitting devices 70 may be prevented. Additionally, the light-emitting devices 70 may be mounted on a portion of the package substrate 52a in which the cavities 56 are formed. Thus, alignment precision of the light-emitting devices 70 may be improved.

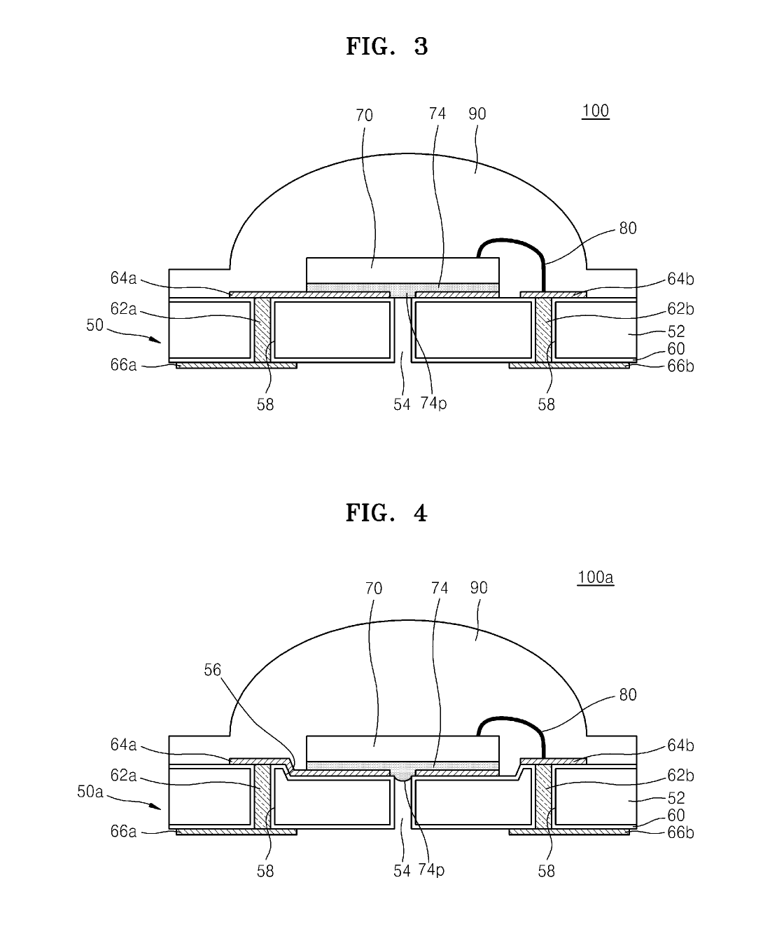

FIG. 3 is a cross-sectional view illustrating a light-emitting device package 100 according to an exemplary embodiment of the inventive concept. FIG. 3 shows the separate light-emitting device package 100 which is formed by using the package substrate 50 which has been described above with reference to FIG. 1.

Referring to FIG. 3, the light-emitting device package 100 includes the package substrate 50, the light-emitting device 70 which is mounted on an upper part of the package substrate 50, and a lens 90 which covers the light-emitting devices 70.

The package substrate 50 may include the substrate 52 in which the first via holes 54 are formed, through substrate vias 62a and 62b, upper and lower wiring lines 64a, 64b, 66a, and 66b.

According to exemplary embodiments of the inventive concept, the substrate 52 may be a semiconductor substrate, such as a silicon substrate. Otherwise, the substrate 52 may be an insulating substrate which is formed by using, for example, alumina, silicon nitride, or silicon oxide.

The first via holes 54 may be formed to pass through the substrate 52. The first via holes 54 may be formed on a location on which the light-emitting device 70 is mounted. Each first via hole 54 may be formed to have a horizontal cross-section of various shapes such as a circle or a rectangle. A sidewall of each first via hole 54 may be formed to have a predetermined inclination from an upper surface of the substrate 52. Otherwise, the sidewall of each first via hole 54 may be formed to be vertical to the upper surface of the substrate 52. FIG. 3 illustrates a cross-section of the light-emitting device package 100 in which one first via hole 54 is formed. However, the number of the first via holes 54 is not limited thereto.

The through substrate vias 62a and 62b may be formed to pass through the substrate 52 and be spaced apart from the first via hole 54. For example, two second via holes 58, which pass through the substrate 52, may be formed, and the through substrate vias 62a and 62b may be formed to respectively fill an inside of the second via holes 58. FIG. 3 shows that the two second via holes 58 are formed so that the first and second through substrate vias 62a and 62b may be formed. However, the number of the second via holes 58 is not limited thereto. The through substrate vias 62a and 62b may include a conductive material such as copper (Cu), aluminum (Al), nickel (Ni), or titanium (Ti). However, a material of the through substrate vias 62a and 62b is not limited thereto. Additionally, the through substrate vias 62a and 62b may be formed of a single material, or formed of a structure in which a plurality of conductive materials are stacked.

An insulating layer 60 may be formed on upper and lower surfaces of the substrate 52 and on sidewalls of the substrate 52 exposed through the first and second via holes 54 and 58, so as to have a predetermined thickness. For example, the insulating layer 60 may include an insulating material such as silicon oxide, silicon nitride, aluminum oxide, or silicon carbide. If the substrate 52 is formed of a conductive material such as silicon, the insulating layer 60 may be formed between the substrate 52 and the through substrate vias 62a and 62b, and may function to electrically insulate the through substrate vias 62a and 62b from the substrate 52. If the substrate 52 is formed of an insulating material, the insulating layer 60 may not be formed.

The first upper wiring line 64a and the second upper wiring line 64b may be formed on an upper surface of the substrate 52, so as to be respectively connected to the first through substrate vias 62a and the through substrate vias 62b. The first upper wiring line 64a may be formed to overlap with the light-emitting device 70. The first upper wiring line 64a may not be formed to overlap with the first via hole 54.

The first lower wiring line 66a and the second lower wiring line 66b may be formed on a lower surface of the substrate 52, so as to be respectively connected to the first through substrate vias 62a and the through substrate vias 62b. Accordingly, the first upper wiring line 64a is electrically connected to the first lower wiring line 66a via the first through substrate via 62a. The second upper wiring line 64b is electrically connected to the second lower wiring line 66b via the second through substrate via 62b.

If the substrate 52 is formed of an electrically-conductive material such as silicon, the insulating layer 60 may be formed between the upper and lower wiring lines 64a, 64b, 66a, and 66b and the substrate 52, thus electrically insulating the upper and lower wiring lines 64a, 64b, 66a, and 66b from the substrate 52.

The light-emitting device 70 may be mounted on the package substrate 50 to overlap with the first via hole 54. For example, the light-emitting device 70 may be a blue light-emitting diode (LED) chip, a green LED chip, a red LED chip, a yellow LED chip, or an ultraviolet (UV) LED chip. However, a type of the light-emitting device 70 is not limited thereto.

A bonding layer 74 may be formed between the light-emitting device 70 and the first upper wiring line 64a. The bonding layer 74 may include a protruding part 74p which protrudes downward from an upper part of the first via hole 54. FIG. 3 shows that the protruding part 74p protrudes downward to the extent the protruding part 74p does not contact the sidewall of the first via hole 54. However, the protruding part 74p may extend downward so that a distal end of the protruding part 74p contacts the sidewall of the first via hole 54.

In exemplary embodiments, the bonding layer 74 may include a eutectic bonding material. The eutectic bonding material refers to a material that may be bonded through heat compression at a temperature of 200 to 700° C. For example, the eutectic bonding material may include a material such as gold-tin (Au—Sn), gold-nickel (Au—Ni), gold-germanium (Au—Ge), aluminum-germanium (Al—Ge), gold-indium (Au—In), silver-tin (Ag—Sn), indium-tin (In—Sn), or silver-tin-copper (Ag—Sn—Cu). The bonding layer 74, which is formed on the lower surface of the light-emitting device 70, may be bonded to the first upper wiring line 64a by using a eutectic bonding method. Thus, reliable and strong bonding may be realized.

A bonding wire 80 may be formed to connect an upper surface of the light-emitting device 70 to the second upper wiring line 64b. For example, the light-emitting device 70 may be a vertical-type light-emitting chip. In this case, an, electrode (not illustrated) may be formed in a bottom portion of the light-emitting device 70, and a p-electrode (not illustrated) may be formed in an upper portion of the light-emitting device 70. Accordingly, the first upper wiring line 64a and the second upper wiring line 64b may be electrically connected to the n-electrode and the p-electrode, respectively.

A fluorescent layer (not illustrated) may be formed on the package substrate 50 so as to cover the light-emitting device 70, and the lens 90 may be formed on the fluorescent layer.

According to the inventive concept, the light-emitting device package 100 includes the first via hole 54 that may function as a suction hole in an area of the package substrate 50 which overlaps with the light-emitting device 70. Accordingly, in a process of mounting the light-emitting device 70, the light-emitting device 70 may be temporarily fixed on the package substrate 50 by performing suction through the first via hole 54, and then, the bonding layer 74 may be formed by performing a high-temperature bonding process. Accordingly, by simultaneously heating the temporarily fixed light-emitting devices 70, a period of time during which the light-emitting device 70 is exposed to a high temperature may be prevented. Thus, damage to or performance deterioration of the light-emitting devices 70 may be prevented, and high reliability may be obtained.

FIG. 4 is a cross-sectional view illustrating a light-emitting device package 100a according to an exemplary embodiment of the inventive concept. FIG. 4 shows the separate light-emitting device package 100a which is formed by using the package substrate 50a which has been described with reference to FIG. 2. Except that the cavity 56 is further formed in the package substrate 50a, the light-emitting device package 100a, shown in FIG. 4, is similar to the light-emitting device package 100 which has been described with reference to FIG. 3. Accordingly, the following description will be provided by focusing on a difference between the light-emitting device package 100a and the light-emitting device package 100.

Referring to FIG. 4, the package substrate 50a may include the substrate 52 in which the first via hole 54 and the cavity 56 are formed, the through substrate vias 62a and 62b, the upper and lower wiring lines 64a, 64b, 66a, and 66b.

The cavity 56 may be formed to overlap with an area on which the light-emitting device 70 is mounted. In order to mount the light-emitting devices 70 in the cavity 56, a size of the cavity 56 may be formed to be larger than a size of the light-emitting devices 70. Additionally, the cavity 56 may be formed to communicate with the first via hole 54.

A depth of the cavity 56 may be formed to be less than a height of the light-emitting device 70. Accordingly, an upper surface of the light-emitting device 70 may be formed on a level which is higher than an upper surface of the package substrate 50. In this case, in a process of mounting the light-emitting device 70, the light-emitting device 70 may be easily attached or bonded by using a collet. Otherwise, a depth of the cavity 56 may be formed to be greater than a height of the light-emitting device 70. In such a case, a reflective layer (not illustrated) may be further formed on an inclined sidewall of the cavity 56. Thus, efficiency of light emission from the light-emitting device 70 to outside of the cavity 56 may be improved.

The first upper wiring line 64a may be formed on an inner wall of the cavity 56. The first upper wiring line 64a may not be formed over the first via hole 54 so that the first upper wiring line 64a may not overlap with the first via hole 54.

The through substrate vias 62a and 62b may be formed on an area on which the cavity 56 is not formed. Alternatively, the through substrate vias 62a and 62b may be formed inside the cavity 56.

The bonding layer 74 may be formed between the light-emitting device 70 and the first upper wiring line 64a. Additionally, the bonding layer 74 may include the protruding part 74p which protrudes downward from an upper part of the first via hole 54. The protruding part 74p protrudes toward an inside of the first via hole 54 at one end of the first via hole 54 which contacts the bonding layer 74, and has a convex shape.

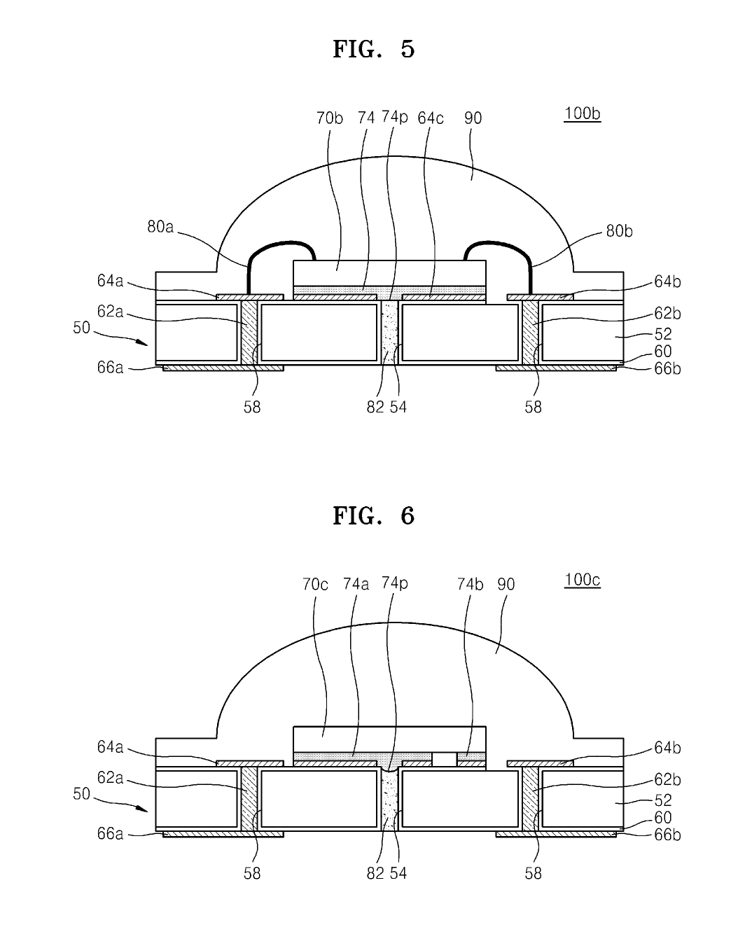

FIG. 5 is a cross-sectional view illustrating a light-emitting device package 100b according to an exemplary embodiment of the inventive concept. The light-emitting package 100b is similar to the light-emitting device package 100 which has been described with reference to FIG. 3, except that an n-electrode and a p-electrode of the light-emitting device 70b are connected to first and second upper wiring lines 64a and 64b, respectively, by using wiring bonding.

Referring to FIG. 5, the light-emitting device 70b, which is mounted on the package substrate 50, may be electrically connected to the package substrate 50 by using first and second bonding wires 80a and 80b.

The light-emitting device 70b may include, for example, a horizontal-type LED chip. In this case, an n-electrode (not illustrated) and a p-electrode (not illustrated) may be formed in an upper portion of the light-emitting device 70b, and an electrical connection with the n-electrode and the p-electrode needs to be formed on the upper surface of the light-emitting device 70b. Accordingly, the first bonding wire 80a and the second bonding wire 80b may be respectively connected from the upper surface of the light-emitting device 70b to the first upper wiring line 64a and the second upper wiring line 64b.

A third upper wiring line 64c may be formed on an upper surface of the package substrate 50, and the light-emitting device 70b may be mounted on the third upper wiring line 64c via the bonding layer 74. For example, the third upper wiring line 64c may be formed in the same patterning process as the first and second upper wiring lines 64a and 64b. Desirably, the third upper wiring line 64c may be formed in an area on which the light-emitting device 70 is mounted, and the third upper wiring line 64c is not formed over the first via hole 54. The first, second and third upper wiring lines 64a, 64b and 64c may be formed not to be electrically connected to each other.

Additionally, a filler 82 may be formed to fill at least a part of the first via hole 54.

According to the inventive concept, the light-emitting device 70b is a top-emission type in which both electrode terminals direct upwards. Thus, a bottom surface of the light-emitting device 70b does not need an electrical connection. However, the light-emitting device 70b is connected to the package substrate 50 via the bonding layer 74 which is a eutectic bonding material of which heat conductivity is excellent, compared to a bonding material that includes an insulating material. Therefore, heat, which may be generated during an operation of the light-emitting device 70b, may be effectively dissipated to the outside of the package substrate 50.

FIG. 6 is a cross-sectional view illustrating a light-emitting device package 100c according to an exemplary embodiment of the inventive concept. Except that the light-emitting device 70c is connected by using a flip-chip method, the light-emitting device package 100c is similar to the light-emitting device package 100 which has been described with reference to FIG. 3.

Referring to FIG. 6, the light-emitting device 70c is mounted on the package substrate 50 by using a flip-chip method.

The light-emitting device 70c may include, for example, a flip-chip type LED chip. In this case, an n-electrode (not illustrated) and a p-electrode (not illustrated) may be formed in a bottom portion of the light-emitting device 70c to be spaced apart from each other. Although not illustrated, an insulating layer (not illustrated) may be formed between the n-electrode and the p-electrode on a lower surface of the light-emitting device 70c. Thus, an electrical short-circuit between both the n- and p-electrodes may prevented.

A first bonding layer 74a and a second bonding layer 74b may be formed on a lower surface of the light-emitting device 70c to be separated from each other. The first bonding layer 74a and the second bonding layer 74b may be formed to be electrically connected to the n-electrode and the p-electrode, respectively. The first bonding layer 74a may contact the first upper wiring line 64a, and the second bonding layer 74b may contact the second upper wiring line 64b.

The first via hole 54 may be formed on the package substrate 50 to overlap with the first bonding layer 74a. The first bonding layer 74a may include the protruding part 74p which protrudes downward from an upper part of the first via hole 54 toward an inside of the first via hole 54.

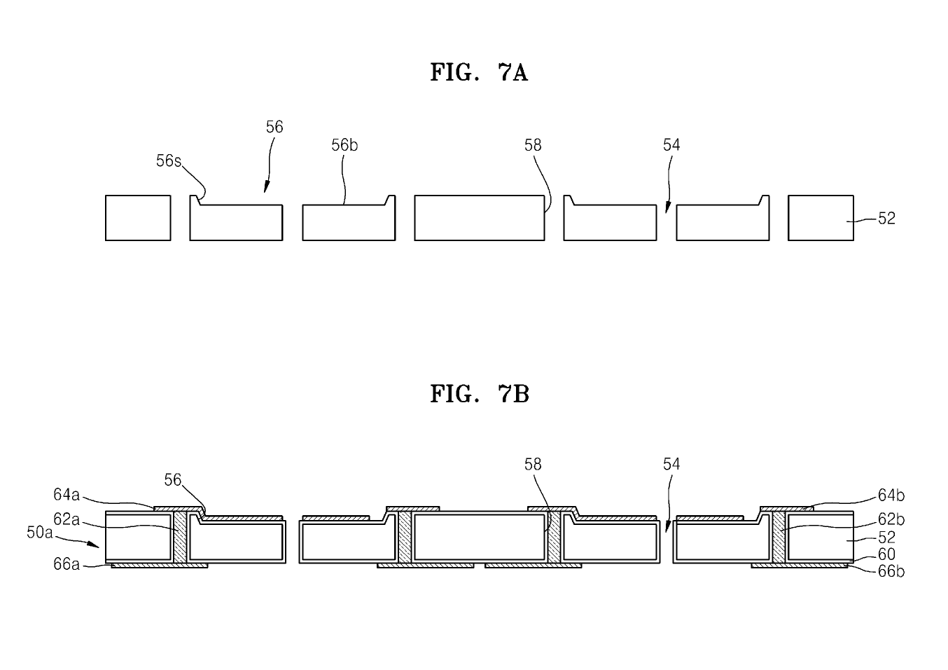

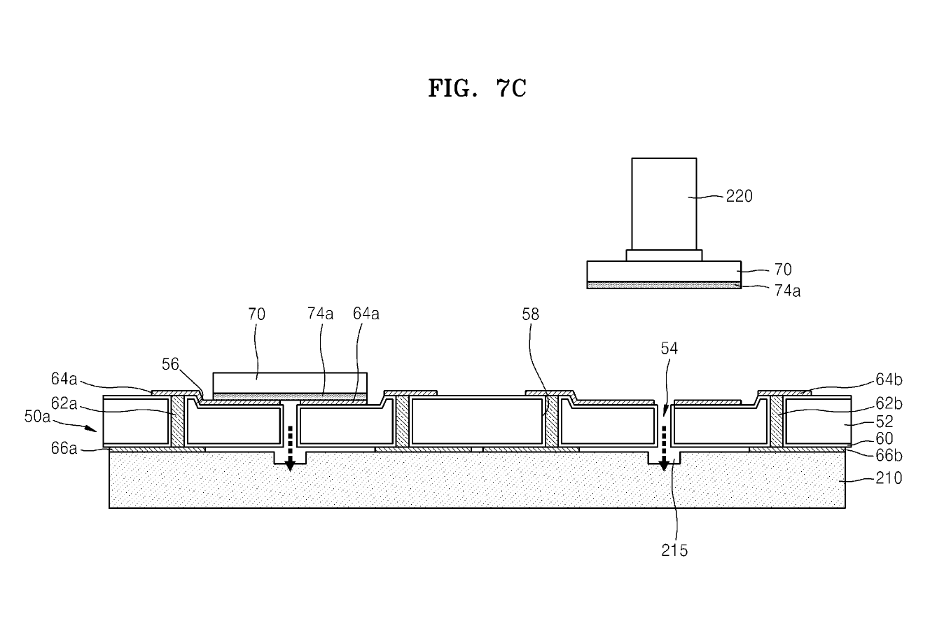

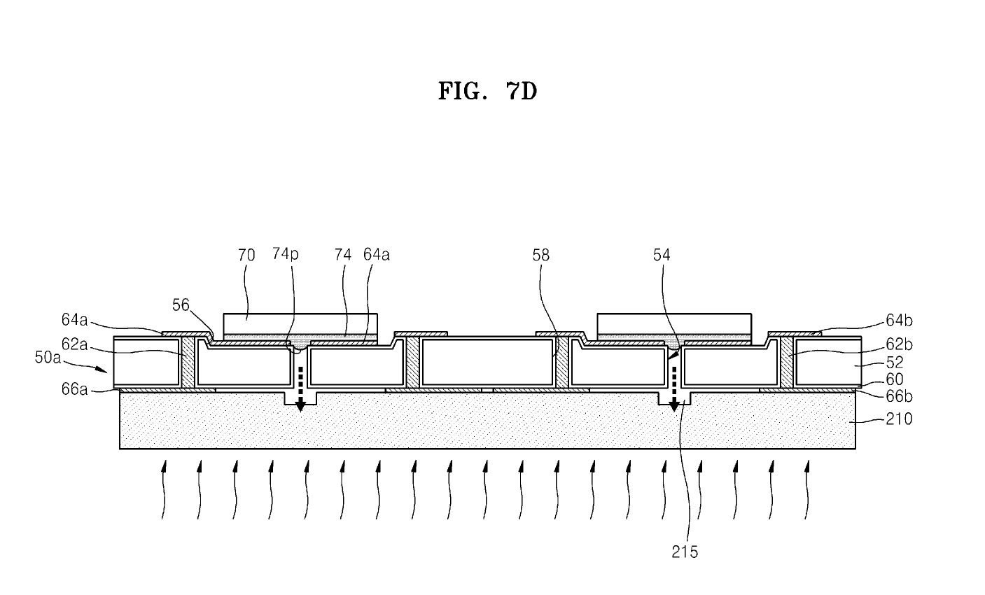

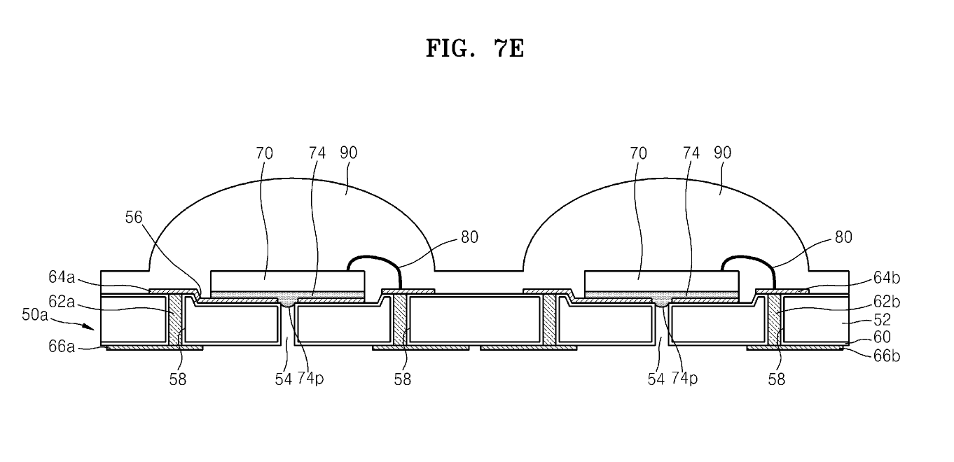

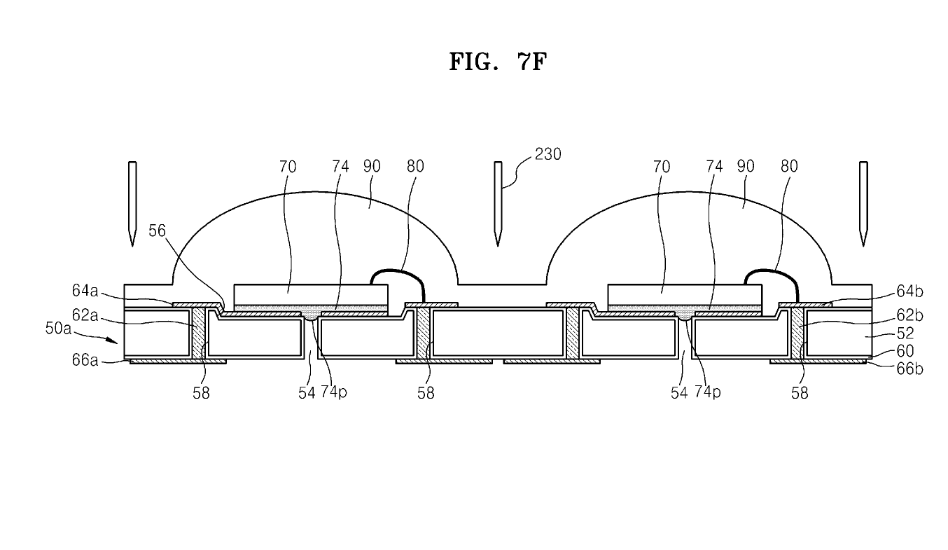

FIGS. 7A through 7F are cross-sectional views illustrating a method of manufacturing a light-emitting device package according to an exemplary embodiment of the inventive concept. The manufacturing method may be a method of manufacturing the light-emitting device package 100a which has been described with reference to FIG. 4.

Referring to FIG. 7A, a plurality of cavities 56 are formed.

The cavities 56 may be formed to have a recessed shape with a predetermined depth from an upper surface of the substrate 52. The cavities 56 may be defined as a sidewall 56s and a bottom part 56b. That is, an upper surface of the substrate 52, which forms the bottom part 56b of the cavities 56, may be formed on a level which is lower than an upper surface of the substrate 52 on which the cavities 56 are not formed. The sidewall 56s of the cavities 56 may be formed to incline at a predetermined angle to an upper surface of the substrate 52 on which the cavities 56 are not formed.

In exemplary embodiments, a mask layer (not illustrated) such as a photoresist pattern may be formed on the substrate 52, and an upper surface of the substrate 52 may be etched using the mask layer as an etching mask to form the cavities 56. The cavities 56 may be formed by a wet etching process or a dry etching process.

A depth of the cavities 56 may vary with a height of a light-emitting device 70 which will be mounted inside the cavities 56, such as the light-emitting device 70 shown in FIG. 7C. In exemplary embodiments, a depth of the cavities 56 may be less than a height of the light-emitting device 70, so that an upper surface of the light-emitting device 70 is formed on a level that is higher than an upper surface of the substrate 52. In other exemplary embodiments, a depth of the cavities 56 may be greater than a height of the light-emitting device 70, so that an upper surface of the light-emitting device 70 is formed on a level that is lower than an upper surface of the substrate 52.

Then, the first via hole 54 and the second via hole 58 may be formed through the substrate 52. The first via hole 54 may be formed in an area of the substrate 52 in which the cavities 56 are formed. FIG. 7A shows that the second via hole 58 is not formed in an area of the substrate in which the cavities 56 are not formed. Alternatively, the second via hole 58 may be formed in an area of the substrate 52 in which the cavities are formed, according to a design of the light-emitting device package.

In exemplary embodiments, the first and second via holes 54 and 58 may be formed by performing a laser drilling process, a wet etching process, or a dry etching process. In exemplary embodiments, sidewalls of the first and second via holes 54 and 58 may be formed to incline at a predetermined angle.

FIG. 7A illustrates one first via hole 54 and two second via holes 58. However, the numbers of the first via holes 54 and the second via holes 58 are not limited thereto. For example, according to a design of the light-emitting device package, or in order to improve heat dissipation characteristics of the light-emitting device package, the number of the second via holes 58 may be increased. Additionally, the first via holes 54 and the second via holes 58 may have a horizontal cross-section in various shapes such as a circle, a rectangle, or an oval. However, a shape of a cross-section of the via holes 54 and 58 is not limited thereto.

Referring to FIG. 7B, the insulating layer 60 may be formed on upper and lower surfaces of the substrate 52, and sidewalls of the substrate 52 which are exposed via the first and second via holes 54 and 58.

In exemplary embodiments, the insulating layer 60 may be formed by using an insulating material such as silicon oxide, silicon nitride, silicon oxy-nitride, aluminum oxide, silicon carbide, or diamond-like carbon (DLC). In exemplary embodiments, the insulating layer 60 may be formed by performing a thermal oxidation process, a chemical vapor deposition (CVD) process, or a physical vapor deposition (PVD) process. For example, the insulating layer 60 may include silicon oxide which is formed by performing a thermal oxidation process on a silicon substrate.

Then, the first and second through substrate vias 62a and 62b may be formed inside the second via hole 58 by filling a conductive material in the second via hole 58. In a subsequent process, the first through substrate via 62a may be electrically connected to the n-electrode (not illustrated) of the light-emitting device 70 which is shown in FIG. 7C, and the second through substrate via 62b may be electrically connected to the p-electrode (not illustrated) of the light-emitting device 70.

In an exemplary process of forming the through substrate vias 62a and 62b, the through substrate vias 62a and 62b may be formed by forming a mask layer (not illustrated) to expose the second via hole 58, forming a seed layer (not illustrated) on an inner wall of the second via hole 58 to have a predetermined thickness, and then, filling a conductive material inside the second via hole 58 on which the seed layer is formed.

The process of forming the through substrate vias 62a and 62b may be, for example, an electroplating process or an electroless plating process. The through substrate vias 62a and 62b may be formed by using Cu, Al, Ni, or Ti. The through substrate vias 62a and 62b may be formed by using a single material, or may be formed to have a structure in which a plurality of conductive materials are stacked.

In exemplary embodiments, before the seed layer is formed, a diffusion barrier layer (not illustrated) may be further formed by using Ti, tantalum (Ta), or tungsten (W).

Then, the first and second upper wiring lines 64a and 64b may be formed on the insulating layer 60 on an upper surface of the substrate 52, and the first and second lower wiring lines 66a and 66b may be formed on the insulating layer 60 on a lower surface of the substrate 52.

In exemplary embodiments, the first upper wiring line 64a may be formed on the insulating layer 60 inside the cavity 56. The first upper wiring line 64a may be conformally formed along a sidewall of the cavity 56, and electrically connected to the first through substrate via 62a. For example, the first upper wiring line 64a may be formed on at least a part of a bottom area of the cavity 56, and the first upper wiring line 64a may be formed not to cover an upper part of the first via hole 54. For example, the first upper wiring line 64a is formed to entirely cover a bottom area of the cavity 56, other than a bottom area of the cavity 56 in which the first via hole 54 is formed. Accordingly, the first upper wiring line 64a may not overlap with the first via hole 54. The second upper wiring line 64b may be spaced apart from the first via hole 54, and may be electrically connected to the second through substrate via 62b.

The first lower wiring line 66a may be formed on the lower surface of the substrate 52 to be electrically connected to the first through via 62a. The second lower wiring line 66b may be formed on the lower surface of the substrate 52 to be electrically connected to the second through via 62b.

In exemplary embodiments, the upper wiring lines 64a and 64b may be formed by using a transparent conductive material such as indium tin oxide (ITO) or indium zinc oxide (IZO). The lower wiring lines 66a and 66b may be formed by using a transparent conductive material such as ITO or IZO, or a conductive material such Al, Ni, or W.

By performing the process which has been described with regard to FIGS. 7A and 7B, the package substrate 50a, in which the first via hole 54, the through substrate vias 62a and 62b, the upper wiring lines 64a and 64b, and the lower wiring lines 66a and 66b are formed, is formed.

Referring to FIG. 7C, the package substrate 50a may be placed on a vacuum chuck 210. For example, the vacuum chuck 210 may be formed as a flat-surface type so that the package substrate 50a may be placed on the vacuum chuck 210. A plurality of suction holes 215 may be formed on the vacuum chuck 210, and thus, the vacuum chuck 210 may be connected to a vacuum suction apparatus (not illustrated) so as to allow air suction through the suction holes 215. In FIG. 7C, the two suction holes 215 are formed in an area which overlaps with the two first via holes 54. The suction holes 215 may be formed in various shapes such as a shape of a pore which is distributed inside the vacuum chuck 210.

Then, the light-emitting device 70, on which a layer to be bonded 74a is formed, is placed on the package substrate 50a. The light-emitting device 70 may be attached to a collet 220, and then, moved to the package substrate 50a. Thus, the light-emitting device 70 may be placed inside the cavity 56 of the package substrate 50a. For example, as illustrated in FIG. 7C, if an area of the cavity 56 is larger than an area of the light-emitting device 70, the light-emitting device 70 may be precisely aligned in the cavity 56. Thus, misalignment of the light-emitting device 70 may be prevented.

The light-emitting device 70 may be temporarily fixed on the package substrate 50a, by performing air suction from the vacuum chuck 210 below the package substrate 50a. The first via hole 54 may function as a suction hole for air suction. The light-emitting device 70, which is placed on the first via hole 54, may be adsorbed to the package substrate 50a by using a vacuum.

Referring to FIG. 7D, a layer to be bonded, such as the layer to be bonded 74a shown in FIG. 7C, is melted by heating the package substrate 50a. Thus, the bonding layer 74 may be formed.

In exemplary embodiments, the vacuum chuck 210 may be formed of a heat-conductive material, and a heating apparatus (not illustrated) may be attached to the vacuum chuck 210. As a temperature of the vacuum chuck 210 increases, a temperature of the package substrate 50a may also be increased. In other exemplary embodiments, a temperature of the package substrate 50a may also be increased by using a heating apparatus (not illustrated) which is not attached to the vacuum chuck 210. If a temperature of the package substrate 50a rises, a temperature of the layer to be bonded 74a, which contacts an upper surface of the package substrate 50a, may also be increased. Thus, a material which forms the layer to be bonded 74a may be melted. Then, the package substrate 50a may be cooled, and thus, the bonding layer 74 contacting the first upper wiring line 64a may be formed.

For example, the package substrate 50a may be heated to a eutectic bonding temperature, that is, a temperature at which the layer to be bonded 74a may be melted and heat-compressed. In exemplary embodiments, the layer to be bonded 74a may be formed by using a material such as Au—Sn, Au—Ni, Au—Ge, Al—Ge, Au—In, Ag—Sn, In—Sn, or Ag—Sn—Cu. The eutectic bonding temperature may be 200 through 700° C. Time of heating the package substrate 50a may vary with composition of a material of the layer to be bonded 74a.

With regard to a conventional wafer level package method, a plurality of light-emitting devices is disposed sequentially one by one on a package substrate, which is heated up to a eutectic bonding temperature, and bonded one by one. Accordingly, when it takes a certain time to move a respective light-emitting device to an upper part of the package substrate by using a collet, and align the respective light-emitting device at a determined location on the package substrate, if the number of the light-emitting devices that are mounted on the package substrate (i.e., the number of dies) increases, time for which the package substrate is maintained at a high eutectic bonding temperature, may be increased.

However, according to the inventive concept, the light-emitting devices 70 may be moved to the package substrate 50, and then, temporarily fixed on the package substrate 50a by suctioning air via the first via holes 54. Accordingly, after all of a plurality of the light-emitting devices 70 are aligned on the package substrate 50a, the package substrate 50a may be heated up to the eutectic bonding temperature. That is, the plurality of the light-emitting devices 70 may be bonded simultaneously at the eutectic bonding temperature. Thus, even if the number of the light-emitting devices 70, which are mounted on the package substrate 50a, is increased, a time period of exposing a plurality of light-emitting devices to a high temperature may be identical among a plurality of light-emitting devices. Accordingly, oxidation or deterioration of elements inside the light-emitting devices 70 such as a p-type semiconductor layer, an n-type semiconductor layer, or a light-emitting layer, which may be caused when the light-emitting device 70 is exposed at a high temperature for a long period of time, may be prevented. Therefore, deterioration of performance of the light-emitting devices 70 may be prevented.

When the layer to be bonded 74a is melted and compressed, and thus, the bonding layer 74 is formed, the protruding part 74p may be formed on an area of the bonding layer 74 which is located on an upper part of the first via hole 54. According to a temperature of heating a material of the bonding layer 74 and the package substrate 50a which is used for bonding, the protruding part 74p may extend to a part of an inner wall of the first via hole 54.

Referring to FIG. 7E, by cooling the package substrate 50a, a structure, in which the light-emitting device 70 is mounted on the first upper wiring line 64a of the package substrate 50a by using the bonding layer 74, may be formed. An upper part of the first via hole 54 may be covered by the bonding layer, and an inside of the first via hole 54, which is formed below the bonding layer 74, may be still vacant. Alternatively, the first via hole 54 may be filled with a filler (not illustrated) in a subsequent process.

Then, an upper surface of the light-emitting device 70 and the second upper wiring line 64b may be connected to each other by using a wire bonding method. As described above, a p-electrode (not illustrated), which is formed in an upper portion of the light-emitting device 70, may be connected to the second upper wiring line 64b via a bonding wire 80.

A lens 90, which covers the light-emitting device 70 on the package substrate 50a, may be formed. The lens 90 may be formed as a convex lens or by performing a transfer molding method, by using epoxy or silicon. For example, a lens mold (not shown) may be disposed on the package substrate 50a, and a silicon material (not shown) may be injected into the lens mold, and then the silicon mold may be hardened to form the lens 90. The lens 90 may function to form a pattern of emitted light.

Although not illustrated, before the lens 90 is formed, a fluorescent layer (not illustrated) may be further selectively formed on the light-emitting device 70. For example, the fluorescent layer may be formed to have an even thickness by using a screen printing method or a spray process. The fluorescent layer may convert or adjust a wavelength of light that is emitted from the light-emitting device 70.

Referring to FIG. 7F, the package substrate 50a may be separated into respective light-emitting packages. For example, the light-emitting packages 100a, which are shown in FIG. 4 and respectively include the one light-emitting device 70, may be formed by sawing the package substrate 50a by using a blade 230.

According to the inventive concept, a plurality of the light-emitting devices 70 are temporarily fixed on the package substrate 50a in which the first via hole 54 is formed, and then, the plurality of light-emitting devices 70 may be attached to the package substrate 50a simultaneously by heating the package substrate 50a. Accordingly, performance deterioration of the light-emitting device 70, which may occur due to an exposure to a high temperature for a long period of time in a case that the light-emitting devices 70 are bonded one by one, may be prevented. Additionally, since the cavity 56 is formed on the package substrate 50a, the light-emitting devices 70 may be easily aligned.

In FIGS. 7A through 7F, the light-emitting devices 70 are mounted on the package substrate 50a in which the cavity 56 is formed. Alternatively, the light-emitting devices 70 may be mounted on a package substrate in which the cavity 56 is not formed, such as the package substrate 50 shown in FIG. 3.

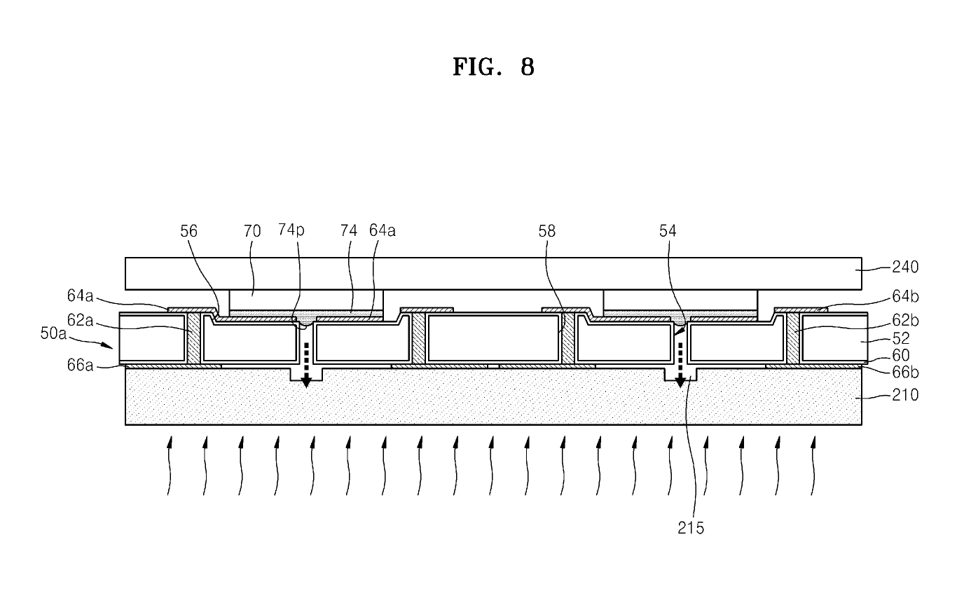

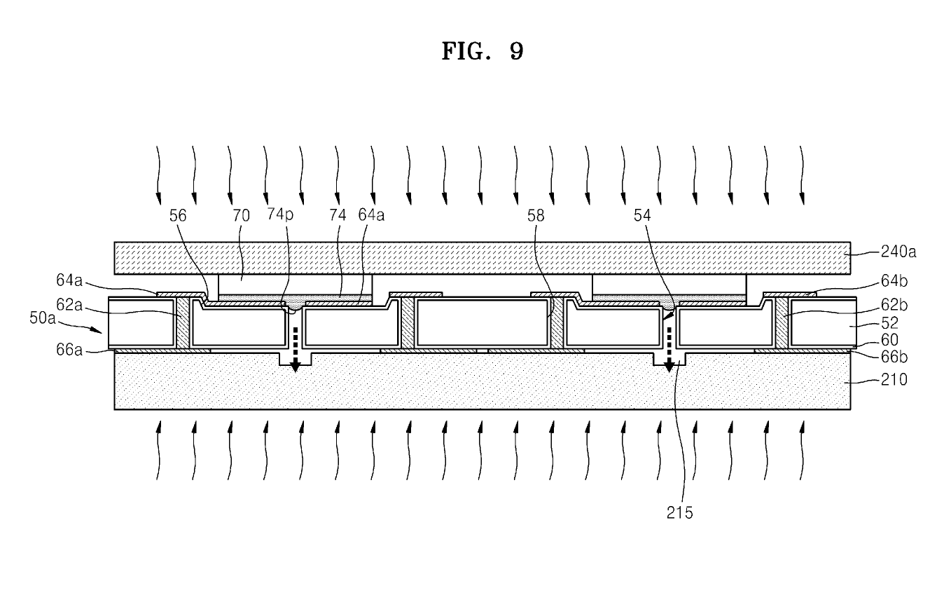

FIG. 8 is a cross-sectional view illustrating a method of manufacturing a light-emitting device package according to another exemplary embodiment of the inventive concept. The method of manufacturing the light-emitting device package is similar to the method described with regard to FIGS. 7A through 7F, except that a pressure cover 240 is further used for a bonding process. Thus, only a difference therebetween will be described below.

First, by performing the processes, which are described with regard to FIGS. 7A through 7C, a plurality of the light-emitting devices 70 are disposed on the package substrate 50a. Then, the light-emitting devices 70 may be temporarily fixed on the package substrate 50a by performing suction from the vacuum chuck 210.

Then, referring to FIG. 8, a predetermined pressure may be applied onto a plurality of light-emitting devices 70 by using the pressure cover 240. Then, the vacuum chuck 210 may be heated so as to increase a temperature of the package substrate 50a. Then, a layer to be bonded, such as the layer to be bonded 74a shown in FIG. 7C, is heat-compressed, and thus, the bonding layer 74 may be formed.

The pressure cover 240 may be formed to have an area which is similar to or larger than an area of the package substrate 50, so that the pressure cover 240 may simultaneously contact the plurality of light-emitting devices 70 which are mounted on the package substrate 50a. According to exemplary embodiments of the inventive concept, the pressure cover 240 may be formed by using a heat-resistant resin or a heat-resistant tape which is attached to a ring mount.

As illustrated in FIG. 8, if the cavity 56 is formed on the package substrate 50a, a depth of the cavity 56 is formed to be less than a height of the light-emitting device 70. Thus, the pressure cover 240 may simultaneously contact a plurality of the light-emitting devices 70. Alternatively, if the cavity 56 is not formed on the package substrate 50a, the pressure cover 240 may simultaneously contact an upper surface of a plurality of the light-emitting devices 70.

According to the inventive concept, when a temperature of the package substrate 50a rises to a eutectic bonding temperature, and thus, the bonding layer 74 is formed, the pressure cover 240 may apply an even pressure to all of the plurality of light-emitting devices 70. Accordingly, stress concentration on a part of the light-emitting devices 70 may be prevented, and the plurality of light-emitting devices 70 may be attached to the package substrate 50a to have a uniform adhesive strength.

Additionally, in a eutectic bonding process of the bonding layer 74, a material of the bonding layer 74, which is partially melted, may protrude to an area of the first via hole 54, and then, may be solidified, thus forming the protruding part 74p. Accordingly, even if a thickness dispersion in the layer to be bonded 74a is large, as a pressure is applied so that an upper surface of the light-emitting device 70 may be formed on an even level, a part of a material of the bonding layer 74 may protrude more into an inside of the first via hole 54. That is, a height of the bonding layer 74 is uniformly formed by using the pressure cover 240 and the first via hole 54. Accordingly, the light-emitting devices 70, which are mounted on the package substrate 50a, may be formed to entirely have an even height. In FIG. 8, the protruding part 74p extends to a part of an inside of the first via hole 54. Alternatively, according to a temperature of heating the package substrate 50a and a material of the bonding layer 74, the protruding part 74p may be barely formed, and the bonding layer 74 may be substantially formed to have an even surface.

FIG. 9 is a cross-sectional view illustrating a method of manufacturing the light-emitting device package according to another exemplary embodiment of the inventive concept. The method of manufacturing the light-emitting device package is similar to the method described with regard to FIGS. 7A through 7F, except that a heat-conductive pressure cover 240a is used for a bonding process. Thus, only a difference therebetween will be described below.

First, by performing the processes, which are described with regard to FIGS. 7A through 7F, a plurality of light-emitting devices 70 are disposed on the package substrate 50a. Then, the light-emitting devices 70 may be temporarily fixed on the package substrate 50a by performing suction from the vacuum chuck 210.

Referring to FIG. 9, a predetermined pressure may be applied onto a plurality of the light-emitting devices 70 by using the pressure cover 240a. The vacuum chuck 210 and the pressure cover 240a are simultaneously heated so that heat is transferred from both sides, i.e., from a lower part of the package substrate 50a and an upper part of the light-emitting devices 70. Thus, a temperature of the package substrate 50a may be increased more quickly. For example, the pressure cover 240a may be formed of a heat-conductive metal such as Cu, Al, iron (Fe), or Ni.

According to the inventive concept, a time for the package substrate 50a to reach a eutectic bonding temperature and a time for which the bonding layer 74 is formed may be shortened. Accordingly, deterioration of elements inside the light-emitting devices 70 or performance deterioration of the light-emitting devices 70, which may occur when the elements or the light-emitting devices 70 are exposed to a high temperature for a long period of time, may be prevented.

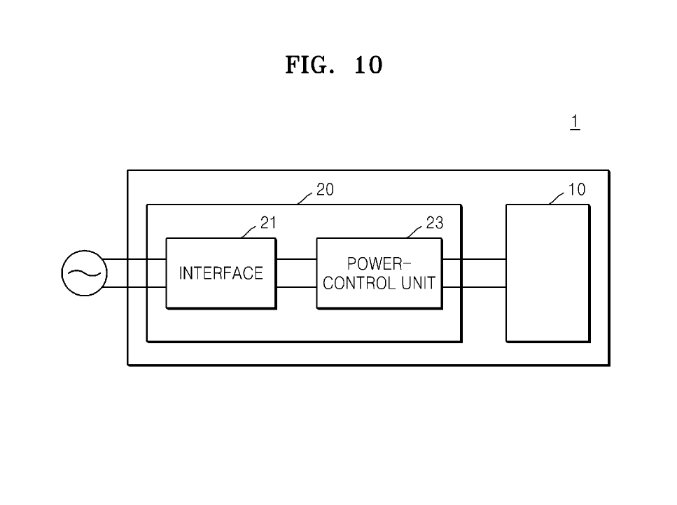

FIG. 10 is a configuration map of a light-emitting device system 1 which employs a light-emitting device package 10 according to an exemplary embodiment of the inventive concept.

Referring to FIG. 1, the light-emitting device system 1 may include the light-emitting device package 10 and a power-supply unit 20 for supplying power to the light-emitting device package 10.

The light-emitting device package 10 may include light-emitting packages 100, 100a, 100b, and 100c, according to exemplary embodiments of the inventive concept.

The power-supply unit 20 may include an interface 21 for receiving a power supply, and a power-control unit 23 for controlling power supplied to the light-emitting device package 10. The interface 21 may include a fuse for shutting off over current and an electromagnetic interference (EMI) filter for suppressing an EMI signal. Power may be supplied from outside or from a built-in battery. If alternating current (AC) power is input as a power source, the power-control unit 23 may further include a rectifying unit for converting AC into direct current (DC), and a constant-voltage control unit for converting a voltage into a voltage which is suitable for the light-emitting device package 10. If power is supplied from a DC power source that has a voltage suitable for the light-emitting device package 10, for example, a battery, the rectifying unit or the constant-voltage control unit may not be included. Additionally, a device, such as an AC-LED, may be employed as a light-emitting device of the light-emitting device package 10, and AC power may be directly supplied to the light-emitting package 10. In such a case, the rectifying unit or the constant-voltage control unit may not be included.

The light-emitting device system 1 is a lighting apparatus that may be used for an LED tube, flat-panel lighting, or a lamp. The light-emitting device system 1 may be also used for a liquid-crystal display (LCD) apparatus of a cellular phone, a back-light unit (BLU) of a TV, or a car.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A light-emitting device package, comprising:
a package substrate including at least one via hole;
a light-emitting device mounted on the package substrate, the light-emitting device overlapping with the at least one via hole; and
a bonding layer formed between the light-emitting device and the package substrate, the bonding layer including a eutectic bonding material.

2. The light-emitting device package of claim 1, wherein the bonding layer overlaps with the at least one via hole, and covers an upper part of the at least one via hole.

3. The light-emitting device package of claim 1, wherein the bonding layer comprises:
a protruding part which protrudes downwards in an area in which the bonding layer overlaps with the at least one via hole.

4. The light-emitting device package of claim 3, wherein the protruding part extends to a sidewall of the at least one via hole.

5. The light-emitting device package of claim 1, wherein:
a cavity having a predetermined depth from an upper surface of the package substrate is formed on the package substrate, and
the light-emitting device is mounted inside the cavity.

6. The light-emitting device package of claim 5, wherein an area of the cavity is greater than an area of the light-emitting device.

7. The light-emitting device package of claim 5, wherein the cavity communicates with the at least one via hole.

8. The light-emitting device package of claim 1, further comprising:
a through substrate via formed inside the at least one via hole through the package substrate, the through substrate via including a conductive material.

9. The light-emitting device package of claim 1, wherein a part of an inside of the at least one via hole is vacant.

10. The light-emitting device package of claim 1, wherein a part of the inside of the at least one via hole is filled with a filler which is an insulating material.

11. The light-emitting device package of claim 1, wherein the entire inside of the at least one via hole is vacant.

12. A light-emitting device package, comprising:
a package substrate having a plurality of light-emitting device mounting areas; and
a plurality of light-emitting devices respectively mounted in the plurality of light-emitting device mounting areas,
wherein a plurality of via holes pass through the package substrate, and
each of the plurality of via holes is formed in each of the plurality of light-emitting device mounting areas of the package substrate.

13. The light-emitting device package of claim 12, further comprising:
bonding layers formed below the light-emitting devices and comprise a eutectic bonding material; and
wiring lines formed in a part of the plurality of light-emitting device mounting areas on the package substrate,
wherein the bonding layers and the wiring lines contact each other and are electrically connected to each other.

14. The light-emitting device package of claim 13, wherein the bonding layers comprise protruding parts which protrude downwards toward the plurality of via holes in an area which overlaps with the plurality of via holes.

15. The light-emitting device package of claim 14, wherein the protruding parts contact a part of an inner wall of the plurality of via holes.

16. A light-emitting device system comprising:
a power supply unit for supplying power;
one or more light-emitting device packages which receive power from the power supply unit, each package including:
a package substrate including at least one via hole;
a light-emitting device mounted on the package substrate, the light-emitting device overlapping with the at least one via hole;
a bonding layer formed between the light-emitting device and the package substrate, the bonding layer including a eutectic bonding material;
a lens for covering each of the light-emitting devices; and
at least one bonding wire for electrically connecting an upper surface of each light-emitting device to wiring associated with the package substrate.

17. The system of claim 16, wherein the bonding layer overlaps with the at least one via hole, and covers an upper part of the at least one via hole

18. The system of claim 16, wherein the bonding layer comprises:
a protruding part which protrudes downwards in an area in which the bonding layer overlaps with the at least one via hole.

19. The system of claim 18, wherein the protruding part extends to a sidewall of the at least one via hole.

20. The system of claim 16, wherein the power supply unit includes:
an interface for receiving the power supply;
a power control unit for controlling the power supplied to each light-emitting device package.
